(19) United States
(12) Patent Application Publication
(10) Pub. No.: US 2024/0412992 A1
(43) Pub. Date: Dec. 12, 2024

(54) SYSTEM AND METHOD FOR ALIGNING A WAFER TO A CHUCK

(71) Applicant: KLA Corporation, Milpitas, CA (US)

(72) Inventor: Jaime Poris, Boulder Creek, CA (US)

(21) Appl. No.: 18/207,553

(22) Filed: Jun. 8, 2023

(51) Int. Cl. H01L 21/67; H01L 21/66; H01L 21/677; H01L 21/687

(52) U.S. Cl. CPC H01L 21/67265; H01L 21/67766; H01L 21/67778; H01L 21/68785; H01L 22/12; H01L 22/30

(57) ABSTRACT

A wafer-chuck alignment system includes a measurement device including a set of cameras and a feature plate including nominal measurement features. The nominal measurement features correspond to the nominal locations of the pins of a chuck of a process tool to be characterized. A robot is configured to transfer a test wafer between the chuck of a process tool and the measurement device. The test wafer includes pressure-sensitive features distributed across the test wafer which are markable by the pins of the chuck. Once the test wafer is marked by the chuck pins and imaged by the cameras of the measurement device, a controller is configured to determine a misalignment vector between the test wafer and the chuck by comparing measurement images of markings formed on the pressure-sensitive features of the test wafer to calibration images of the nominal measurement features of the feature plate of the measurement device.

### TECHNICAL FIELD

The present invention generally relates to the alignment of wafers on a chuck of a process tool, and, more particularly, to a dedicated measurement wafer including multiple pressure-sensitive features markable by pins of the wafer chuck and a feature plate used as a standard to measure the misalignment between marked pressure-sensitive features and the nominal features of the feature plate.

### BACKGROUND

When loading a wafer onto a chuck, it is desired to center the wafer on the chuck. There are many potential methods to accomplish this task. An integrated pre-aligner performs this task if it is incorporated into a piece of hardware such as a wafer metrology tool. It is not only capable of centering the substrate, the pre-aligned can also angularly orient the wafer, assuming the wafer has a feature associated with the wafer orientation (e.g., a notch on a semiconductor wafer). For other pieces of hardware that accept a wafer (e.g., a semiconductor process tool), there is no pre-aligner and, in these cases, some other procedure must be employed to achieve proper wafer-chuck alignment. Therefore, it would be desirable to provide a system and method for wafer-chuck alignment in these settings.

### SUMMARY

A system for wafer-chuck alignment is disclosed, in accordance with one or more embodiments of the present disclosure. In embodiments, the system includes a robot. In embodiments, the system includes a measurement device including a plate, wherein the plate includes a plurality of nominal measurement features, wherein the measurement device includes a plurality of cameras. In embodiments, the robot is configured to transfer a test wafer between a chuck of a process tool and the measurement device, wherein the test wafer includes a plurality of pressure-sensitive features distributed across the test wafer, wherein a respective pressure-sensitive features is markable by a respective pin of a plurality of pins of the chuck. In embodiments, the system includes a controller. In embodiments, the controller is configured to direct the robot to place a test wafer onto the plurality of pins of the chuck of the process tool such that each pressure-sensitive feature is marked by a corresponding pin of the plurality of pins. In embodiments, the controller is configured to direct the plurality of cameras of the measurement device to acquire a plurality of calibration images of the plurality of nominal measurement features of the plate of the measurement device, wherein the plurality of nominal measurement features correspond to nominal locations of the plurality of pins of the chuck. In embodiments, the controller is configured to direct the robot to transfer the test wafer to the measurement device. In embodiments, the controller is configured to direct the plurality of cameras to acquire a plurality of measurement images of a plurality of markings formed on the plurality of pressure-sensitive. In embodiments, the controller is configured to determine a misalignment vector between the test wafer and the chuck by comparing the plurality of measurement images of the plurality of markings formed on the plurality of pressure-sensitive features to the plurality of calibration images of the plurality of nominal measurement features.

A method for wafer-chuck alignment is disclosed, in accordance with one or more embodiments of the present disclosure. In embodiments, the method includes providing a test wafer including a plurality of pressure-sensitive features distributed across the test wafer. In embodiments, the method includes placing, with a robot, the test wafer onto a plurality of pins of a chuck of a process tool to form a plurality of markings on the plurality of pressure-sensitive features, wherein a respective marking is formed on a respective pressure-sensitive feature. In embodiments, the method includes acquiring, with a plurality of cameras, a plurality of calibration images of a plurality of nominal measurement features formed on a plate of a measurement device, the plurality of nominal measurement features corresponding to nominal locations of the plurality of pins of the chuck. In embodiments, the method includes transferring, with the robot, the test wafer from the chuck of the process tool to the plate of the measurement device. In embodiments, the method includes acquiring, with the plurality of cameras, a plurality of measurement images of the plurality of markings formed on the plurality of pressure-sensitive features. In embodiments, the method includes determining a misalignment vector between the test wafer and the chuck by comparing the plurality of measurement images of the plurality of markings formed on the plurality of pressure-sensitive features to the plurality of calibration images of the plurality of nominal measurement features formed on the plate of the measurement device.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the descriptions and the drawings serve to explain the principles of the disclosure.

### BRIEF DESCRIPTION OF THE DRAWINGS

The numerous advantages of the disclosure may be better understood by those skilled in the art by reference to the accompanying figures.

FIG. 1A illustrates a block diagram view of wafer-chuck alignment system, in accordance with one or more embodiments of the present disclosure.

FIG. 1B illustrates a top view of a feature plate of the wafer-chuck alignment system in an unloaded state, in accordance with one or more embodiments of the present disclosure.

FIG. 1C illustrates a top view of a feature plate of the wafer-chuck alignment system securing a test wafer, in accordance with one or more embodiments of the present disclosure.

FIGS. 2A-2D illustrate views of a test wafer with deformable pressure-sensitive features incorporated into the test wafer view through-holes, in accordance with one or more embodiments of the present disclosure.

FIGS. 3A-3B illustrate views of a test wafer with deformable pressure-sensitive features affixed to a surface of the test wafer, in accordance with one or more embodiments of the present disclosure.

FIGS. 4A-4B illustrate views of a test wafer with color-changing pressure-sensitive features affixed to a surface of the test wafer, in accordance with one or more embodiments of the present disclosure.

FIG. 5 illustrates a process flow diagram depicting a method of wafer-chuck alignment, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

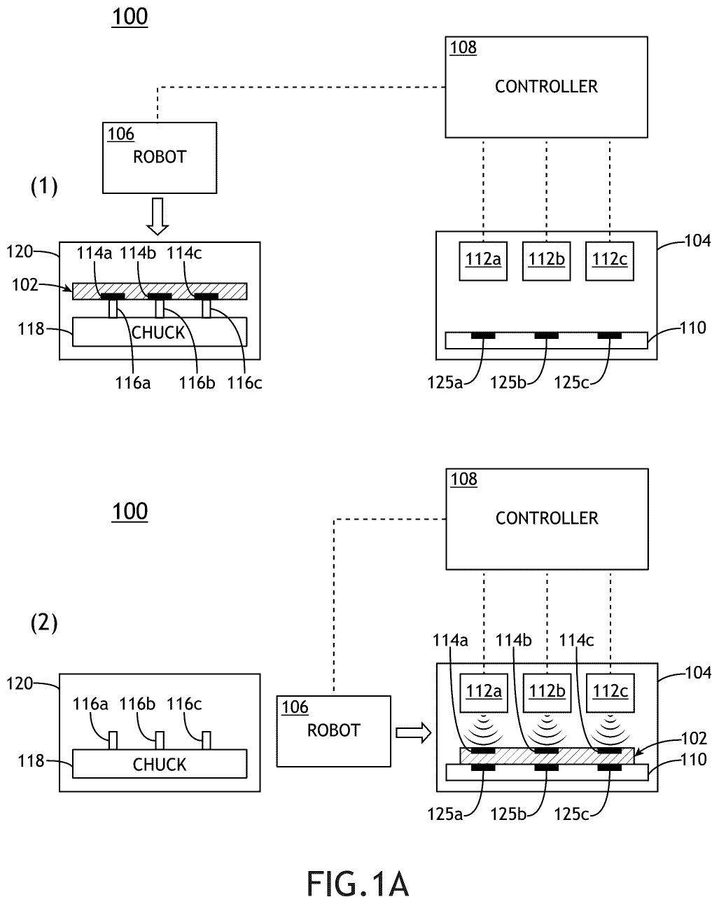

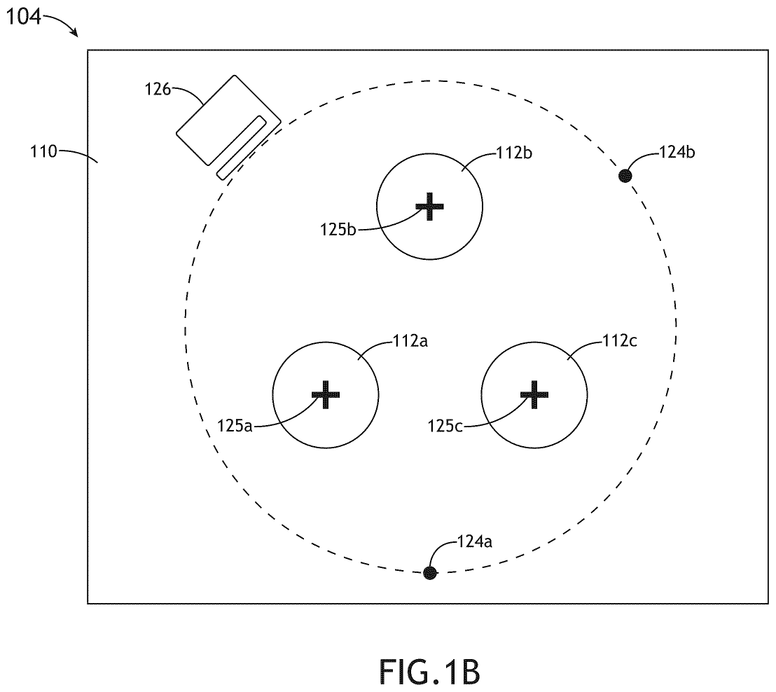

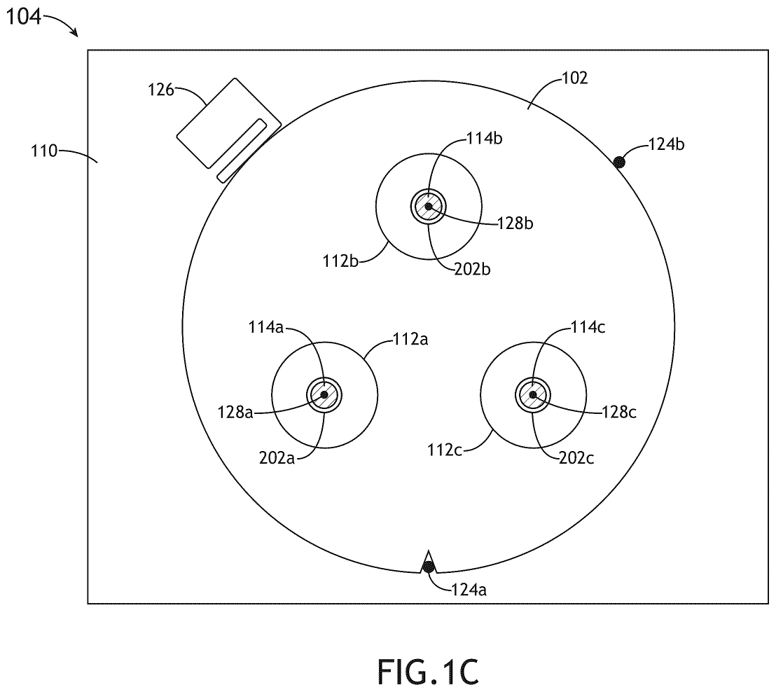

Referring generally to FIGS. 1-5, a system and method for wafer-chuck alignment is described, in accordance with one or more embodiments of the present disclosure.

Embodiments of the present disclosure are directed to a wafer-chuck alignment system utilizing a test wafer equipped with a set of pressure-sensitive features distributed across the test wafer. The pressure-sensitive features are located at positions that correspond to the nominal positions of the pins of the chuck in question. The pressure-sensitive features are marked by the mechanical action caused by the chuck pins that come in contact with the pressure-sensitive features and are deformed (e.g., indented) or change colors. The locations of the markings on the pressure-sensitive features are analyzed and determined through image data obtained through a set of cameras. The locations of the marks on the pressure-sensitive features are then compared to locations of the nominal positions of the chuck pins to determine a misalignment vector between the test wafer and the chuck. Based on the measured misalignment, the system may then adjust wafers placed on the chuck to compensate for the measurement misalignment.

FIG. 1A illustrates a system 100 for wafer-chuck alignment, in accordance with one or more embodiments of the present disclosure. In embodiments, the system 100 includes a test wafer 102, a measurement device 104, a robot 106, and a controller 108. In embodiments, the measurement device 104 may include a feature plate 110 and a set of cameras 112a-112c. In embodiments, the test wafer 102 includes a set of pressure-sensitive features 114a-114c distributed across the test wafer 102. In embodiments, the pressure-sensitive features 114a-114c may become visually altered when placed on a set of pins 116a-116c (e.g., lift pins) of a chuck 118 of a process tool 120. In this sense, the pressure-sensitive features 114a-114c may visually indicate (e.g., via deformation or change in color) the location where pins 116a-116c of the chuck 118 of the process tool 120 contacted the test wafer 102. In embodiments, the feature plate 110 includes a set of nominal features 125a-125c corresponding to the precise location of the pins 116a-116c of the chuck 118 of the process tool 120. In embodiments, cameras 112a-112c may be positioned above the nominal features 125a-125c.

In embodiments, the test wafer 102 is formed from at least one of carbon fiber, silicon, aluminum, or quartz.

FIG. 1B depicts a top view of the measurement device 104, in an unloaded state (i.e., no test wafer present), including the feature plate 110 with nominal features 125a-125c. The location where the nominal features 125a-125c are formed may be determined by information related to the chuck 118. For example, a CAD model of the chuck 118 may be utilized to determine the location of the location of the pins 116a-116c of the chuck 118 and, therefore, dictate the placement of the nominal features 125a-125c on the feature plate 110. The nominal features 125a-125c may be formed by any manner of marking. For example, the nominal features 125a-125c may be formed by mechanical marking, machining, chemical etching, painting, adhesive marking, or the like. In this embodiment, the nominal features 125a-125c are depicted as crosses. It is noted herein that such a marking is not a limitation on the scope of the present disclosure and is provided merely for illustrative purposes. Any form of marking is suitable within the scope of the present disclosure. In an alternative embodiment, the nominal features 125a-125c may include silicon chips with etched features affixed to depressions in the feature plate 110.

In embodiments, cameras 112a-112c are located directly over the corresponding nominal features 125a-125c. For example, a stable bridge securing the cameras 112a-112c may be used that suspends the cameras 112a-112c over the nominal features 125a-125c. In embodiments, the controller 108 may direct the cameras 112a-112c to acquire one or more images of each of the nominal features 125a-125c. In embodiments, the controller 108 may apply a calibration process. The calibration process may include the application of pattern recognition routines/software to the images to identify the position of the nominal features 125a-125c. The calibrated positions of the nominal features 125a-125c may then be used to measure the misalignment of the test wafer 102 on the chuck 118 by comparing the locations of the markings on the pressure-sensitive features 114a-114c caused by the pins 116a-116c of the chuck 118 to the positions of the nominal features 125a-125c acquired in the calibration step.

FIG. 1C illustrates depicts a top view of the measurement device 104, in a loaded state (i.e., test wafer loaded), in accordance with one or more embodiments of the present disclosure. In embodiments, the pressure-sensitive features 114a-114c of the test wafer 102 are marked by the pins 116a-116c of the chuck 118. In turn, the test wafer 102 is removed from the chuck 118 and placed on the feature plate 110. In embodiments, the test wafer 102 is aligned on the feature plate 110 via alignment pegs 124a, 124b (or other mechanical means). The alignment pegs 124a, 124b ensure the pressure-sensitive features 114a-114c are positioned within the field-of-views of the corresponding cameras 112a-112c. For example, the first peg 124a aligns the notch of the test wafer 102, while the second peg 124b may be located at another location along the circumference of the test wafer 102 (e.g., 120 degrees from the notch). The notch peg 124a may be located at a radius slightly less (e.g., 149 mm) than nominal radius (e.g., 150 mm) of the test wafer 102 so the notch peg 124a touches the notch at two positions (e.g., left and right edges of the notch). The alignment peg 124b may be located at radius slightly larger (e.g., 151 mm) than the nominal radius of the test wafer 102 (e.g., 150 mm from the center). In embodiments, a clamp 126 (e.g., plastic clamp) may be affixed (e.g., glued) to the surface of the plate 110 and away from both pegs 124a, 124b. The clamp 126 may apply a force to the wafer 102 causing the test wafer 102 to push against the two pegs 124a, 124b. In embodiments where the test wafer 102 does not possess a notch, a three-peg configuration may be employed to orient the wafer.

In embodiments, after the test wafer 102 is aligned on the fixture plate 110 with the pressure-sensitive features 114a-114c located beneath cameras 112a-112c, respectively, the camera 112a-112c may image the pressure-sensitive features 114a-114c. Based on the images of the pressure-sensitive features 114a-114c, a position of the markings 128a-128c on each of the pressure-sensitive features 114a-114c may be determined (e.g., positions determined with pattern recognition software).

In embodiments, following determination of the positions of the markings 128a-128c, a misalignment vector may be determined. In embodiments, the misalignment vector may be calculated by comparing the positions of the nominal features 125a-125c to the positions of the markings 128a-128c. For example, in the case where the markings 128a-128c and nominal features 125a-125c define geometric shapes, the misalignment vector may be determined by comparing a first center of the geometric shape (e.g., triangle, rectangle, octagon, circle, etc.) defined by the nominal features 125a-125c (noting in practice there may be more than 3 features) to a second center of the geometric shape defined by the markings 128a-128c (noting in practice there may be more than 3 features). For instance, in the case where the markings 128a-128c and nominal features 125a-125c define equilateral triangles, a first circle may be fit to the equilateral triangle defined by the nominal features 125a-125c on the plate 110 and a second circle may be fit to the equilateral triangle defined by markings 128a-128c on the pressure-sensitive features 114a-114c. A center for each circle may be determined and a difference between the two centers may be calculated. This difference may be interpreted as the misalignment vector between the chuck 118 and the test wafer 102. In embodiments where the test wafer 102 is inverted on the feature plate 110 relative to its position in on the chuck 118 (as shown in FIG. 1A), the center position may need mirrored through this line to arrive at the corrected center location.

In embodiments, one the misalignment vector between the chuck 118 and the test wafer 102, the system 100 may adjust the position of subsequent wafers (e.g., production wafers) to offset the misalignment vector.

While FIGS. 1A-1C depict three pressure-sensitive features 114a-114c, such a configuration should not be interpreted as a limitation on the scope of the present disclosure. It is noted herein that the test wafer 102 may include any number of pressure-sensitive features arranged in any suitable pattern. For example, the test wafer 102 may include two pressure-sensitive features, three pressure-sensitive features, four pressure-sensitive features, five pressure-sensitive features, and so on. The pressure-sensitive features 114a-114c and the nominal features 125a-125c may be arranged in any geometric pattern including, but not limited to, a polygon or an ellipse. The pressure-sensitive features 114a-114c and the nominal features 125a-125c may be more specifically arranged in any geometric pattern including, but not limited to a line pattern, a triangular pattern (e.g., equilateral triangle), a quadrilateral pattern (e.g., a parallelogram or trapezoid), a pentagonal pattern, a hexagonal pattern, an octagonal pattern, a circular pattern, and the like. Further, the misalignment vector between the marked pressure-sensitive features 128a-128c and the nominal features 125a-125c need not be calculated using equilateral triangles or a center of the respective patterns. It is noted that any approach to finding a geometric misalignment between the nominal features 125a-125c and the marked pressure-sensitive features 128a-128c may be implemented within the scope of the present disclosure.

The pressure-sensitive features 114a-114c of the test wafer 102 may include any pressure-sensitive feature known in the art. For example, the pressure-sensitive features may include, but are not limited to, deformable features fabricated from a deformable material (e.g., metal) or color-changing features fabricating from a material that changes color upon application of pressure.

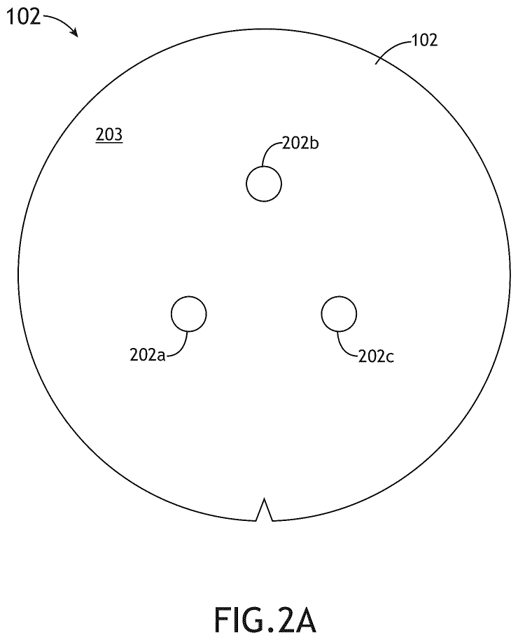

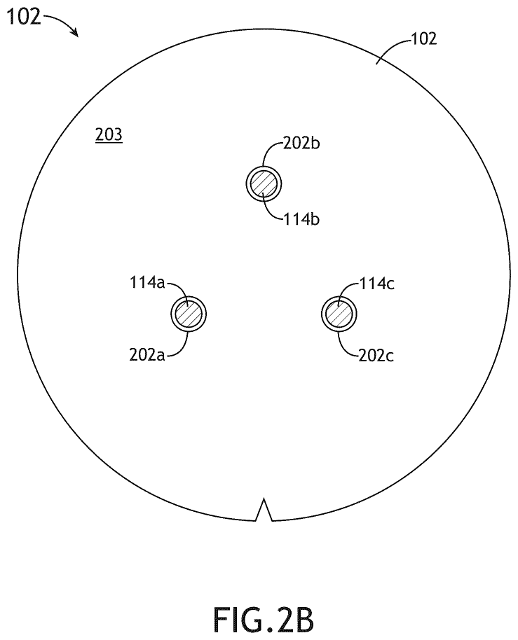

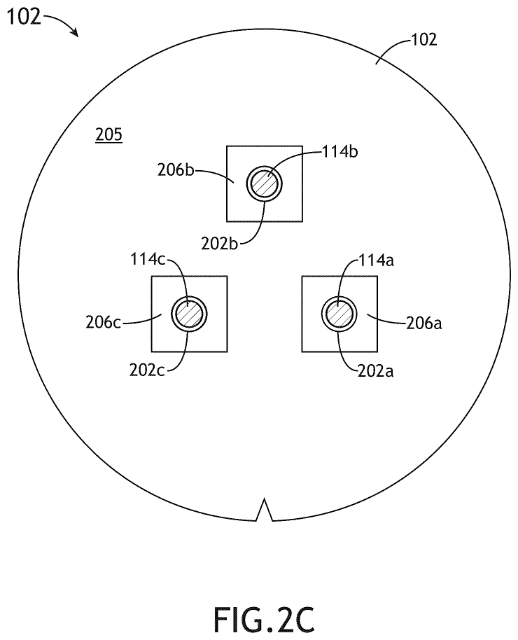

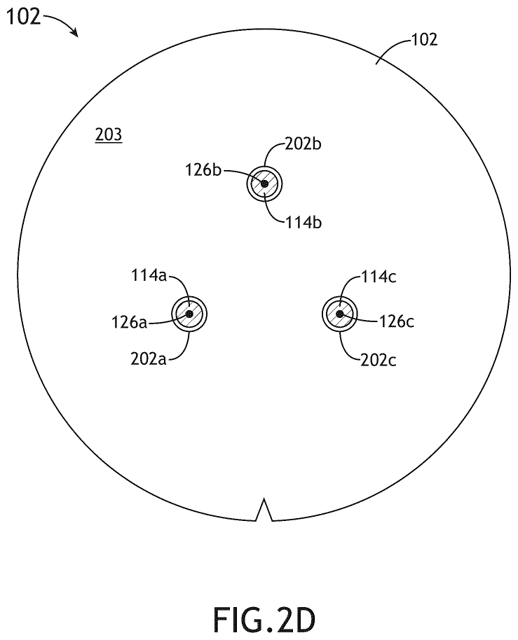

FIGS. 2A-2D depict views of the test wafer 102 formed with deformable pressure-sensitive features 114a-114c, in accordance with one or more embodiments of the present disclosure. FIGS. 2A and 2B depict views of the bottom surface 203 of the test wafer 102, while FIG. 2C depicts the top 205 of the test wafer 102. For purposes of this disclosure, the bottom surface 203 is interpreted to mean the surface that faces the chuck 118 when the test wafer 102 is placed on the chuck 118 for pin marking. The bottom surface 203 then faces toward the cameras 112a-112c during measurement on the feature plate 110.

In embodiments, as shown in FIG. 2A, the test wafer 102 may include a set of pass-through holes 202a-202c. In embodiments, as shown in FIG. 2B, deformable features 114a-114c may be inserted into the respective pass-through holes 202a-202c such that the surface of the features 114a-114c are flush with the bottom surface 203 of the test wafer 102. The surfaces of features 114a-114c may then contact the pins 116a-116c of the chuck 118 and, upon contact, the pins 116a-116c create indentations in the deformable features 114a-114c. These indentations then serve as the markings 128a-128c as previously described herein. The deformable features may be formed from any deformable material known in the art, such as, but not limited to, one or more metals (e.g., indium, tin, copper, or lead etc.), one or more plastics, and the like. In embodiments, the deformable material (e.g., the metal or the plastic) is 300 to 800 μm thick. In embodiments, as shown in FIG. 2C, deformable features 114a-114c may be inserted into the respective pass-through holes 202a-202c and secured to the test wafer 102 from the top surface 205 of the wafer 102. For example, the deformable features 114a-114b may be secured to the test wafer 102 and suspended within respective pass-through holes 202a-202c via adhesive tape (e.g., Kapton tape) sections 206a-206c. FIG. 2D depicts the bottom surface 203 of the test wafer 102 following indentation of the deformable features 114a-114c by the chuck pins 116a-116c.

In embodiments, each deformable feature 114a-114c is secured within a respective through-hole of the test wafer and spans a portion of the respective through-hole, wherein the respective deformable feature 114a-114c does not contact an edge of the respective through-hole.

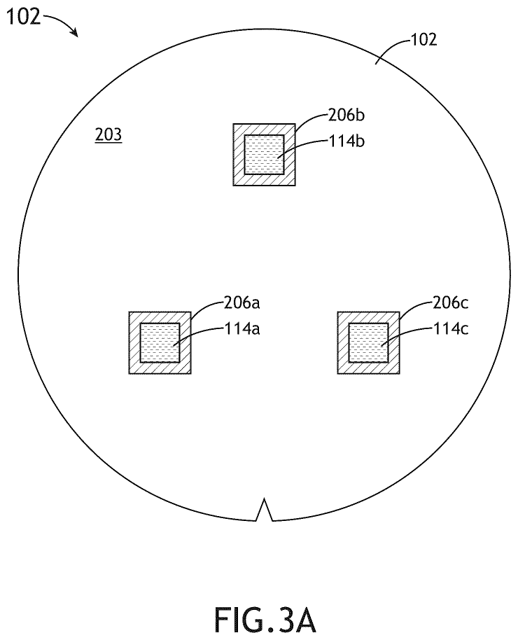

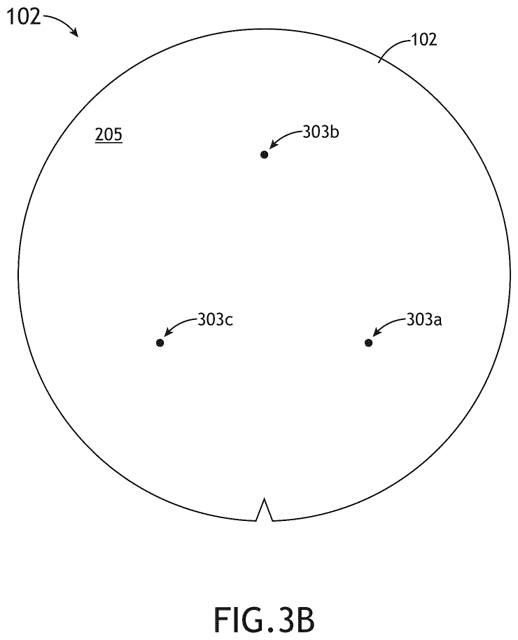

FIGS. 3A-3B depict views of the test wafer 102 formed with deformable pressure-sensitive features 114a-114c, in accordance with one or more embodiments of the present disclosure. FIG. 3A depicts the bottom surface 203 of the test wafer 102 with deformable features 114a-114c adhered to the bottom surface via adhesive tape sections 206a-206c. It is noted that, in this embodiment, the deformable features 114a-114c may also be affixed to the bottom surface 203 of the test wafer 102 via an adhesive (e.g., glue), via a welding process, or via a melt process. FIG. 3B depicts the top surface 205 of the test wafer 102 indicating the lack of pass-through holes and highlighting the positions 303a-303c of the features 114a-114c located on the bottom surface 203.

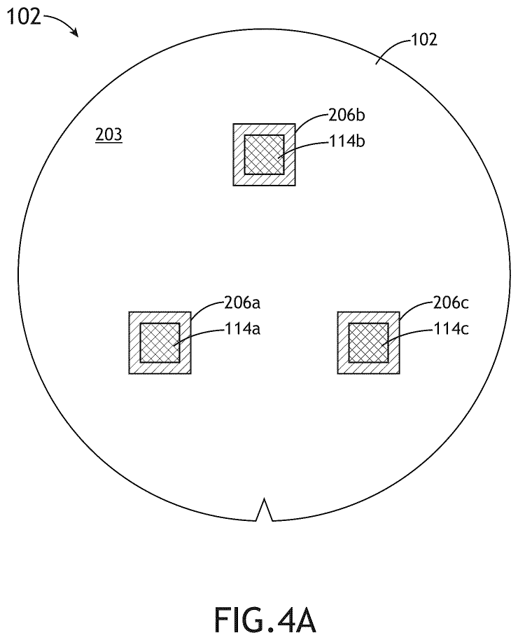

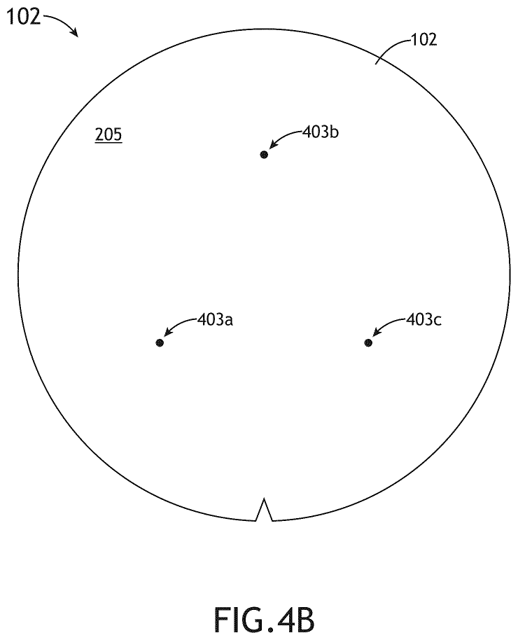

FIGS. 4A-4B depict views of the test wafer 102 formed with color-changing pressure-sensitive features 114a-114c, in accordance with one or more embodiments of the present disclosure. FIG. 4A depicts the bottom surface 203 of the test wafer 102 with color-changing features 114a-114c adhered to the bottom surface via adhesive tape sections 206a-206c. It is noted that, in this embodiment, the color-changing features 114a-114c may also be affixed to the bottom surface 203 of the test wafer 102 via an adhesive (e.g., glue) or a melt process. FIG. 4B depicts the top surface 205 of the test wafer 102 indicating the lack of pass-through holes and highlighting the position 403a-403c of the features 114a-114c located on the bottom surface 203. The color-changing material used to fabrication the color-changing features 114a-114c may include any material known in the art that changes color or opacity in response to the application of pressure. In this embodiment, the material may change colors or opacity due to the pressure cause from the chuck pins 116a-116c (e.g., cause by weight of test wafer 102 on pins). One such color-change material includes PRESCALE film from FUJIFILM which turns red where a pressure is applied.

Referring generally to FIGS. 1A-4B, the controller 108 may control various functions of system 100, in accordance with one or more embodiments of the present disclosure.

In embodiments, during operation, in step (1) of FIG. 1A, the controller 108 may direct the robot 106 to place the test wafer 102 onto the set of pins 116a-116c of chuck 118 of the process tool 120. For example, the controller 108 may remove the test wafer 102 from a front opening unified pod (FOUP) container and place the test wafer 102 onto the set of pins 116a-116c. Based on the gravitational force on the test wafer 102, pressure is created between the pins 116a-116c and the pressure-sensitive features 114a-114c of the test wafer 102. In response to this pressure, the pressure-sensitive features 114a-114c are marked (e.g., indentation or color/opacity change) by the set of pins 116a-116c with markings 128a-128c.

It is noted that, in the event the chuck 118 does not have lift pins (e.g., there are cutouts on the chuck 118 that allow the robot arm to drop below the top surface of the chuck), short, temporary “lift pins” can be placed onto the chuck 118 at known, precise locations just for the purpose of the alignment measurement. In addition, alignment holes or threaded holes may be formed on the chuck at the desired pin locations before the process tool is assembled, allowing for temporary lift pins to be more easily installed/removed.

In embodiments, prior to measurement of the test wafer 102, the controller 108 may direct the set of cameras 112a-112c of the measurement device 104 to acquire a set of calibration images of the set of nominal features 122a-122c of the feature plate 110.

In embodiments, in step (2) of FIG. 1A, the controller 108 may direct the robot 106 to transfer the test wafer 102 from the chuck 118 to the feature plate 110 of the measurement device 104. Following positioning of the test wafer 102 on the feature plate 110, the controller 108 may direct the set of cameras 112a-112c to acquire a set of measurement images of the markings 128a-128c formed on the pressure-sensitive features 114a-114c. In turn, the controller 108 may determine a misalignment vector between the test wafer 102 and the chuck 118 by comparing the calibration images of the nominal features 125a-125c to the measurement images of the markings 128a-128c of the pressure-sensitive features 114a-114c. The controller 108 may then direct the robot 106 to adjust a position of a subsequent wafer (e.g., production wafer) on the chuck 118 to correct for the measured misalignment vector.

The controller 108 may include one or more processors and memory. The one or more processors of the present disclosure may include any one or more processing elements known in the art. In this sense, the one or more processors may include any microprocessor-type device configured to execute software algorithms and/or instructions. In embodiments, the one or more processors may consist of a desktop computer, mainframe computer system, workstation, image computer, parallel processor, or other computer system (e.g., networked computer) configured to execute a program configured to operate the system 100, as described throughout the present disclosure. It should be recognized that the steps described throughout the present disclosure may be carried out by a single computer system or, alternatively, multiple computer systems. In general, the term “processor” may be broadly defined to encompass any device having one or more processing elements, which execute program instructions from a non-transitory memory medium. Moreover, different subsystems of the various systems disclosed may include processor or logic elements suitable for carrying out at least a portion of the steps described throughout the present disclosure. Therefore, the above description should not be interpreted as a limitation on the present disclosure but merely an illustration.

The memory medium may include any storage medium known in the art suitable for storing program instructions executable by the associated one or more processors. For example, the memory medium may include a non-transitory memory medium. For instance, the memory medium may include, but is not limited to, a read-only memory, a random-access memory, a magnetic or optical memory device (e.g., disk), a magnetic tape, a solid-state drive, and the like. In embodiments, the memory medium is configured to store one or more results and/or outputs of the various steps described herein. It is further noted that memory may be housed in a common controller housing with the one or more processors. In an alternative embodiment, the memory medium may be located remotely with respect to the physical location of the one or more processors. For instance, the one or more processors may access a remote memory (e.g., server), accessible through a network (e.g., internet, intranet, and the like). In embodiments, the memory medium maintains program instructions for causing the one or more processors to carry out the various steps described through the present disclosure.

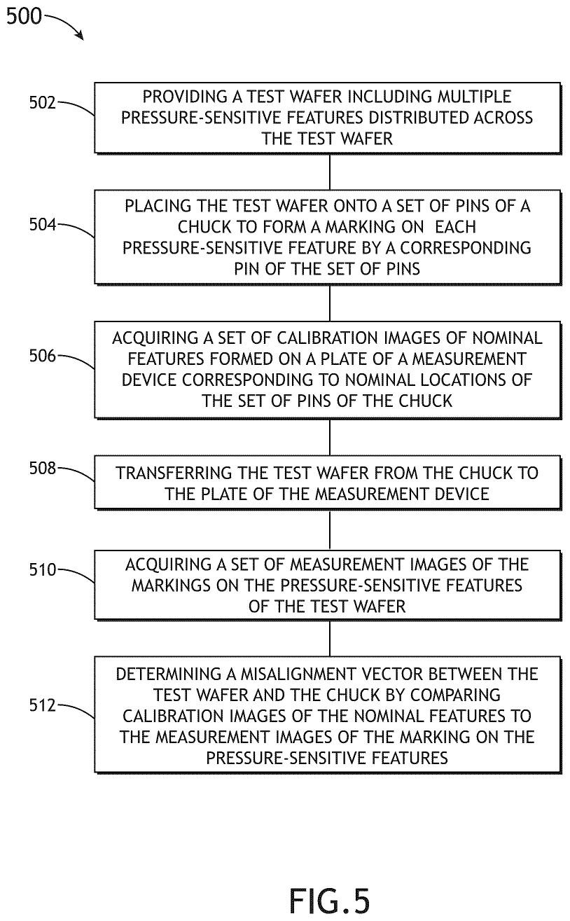

FIG. 5 illustrates a flow diagram depicting a method 500 for aligning a wafer to a chuck, in accordance with one or more embodiments of the present disclosure. It is noted herein that the steps of method 500 may be implemented all or in part by system 100. It is further recognized, however, that the method 500 is not limited to the system 100 in that additional or alternative system-level embodiments may carry out all or part of the steps of method 500.

In step 502, a test wafer including multiple pressure-sensitive features distributed across the test wafer is provided. In step 504, the test wafer is placed onto a set of pins of a chuck to form a marking on each pressure-sensitive feature by a corresponding pin of the set of pins. In step 506, a set of calibration images of the nominal features formed on a feature plate of a measurement device are acquired, where the nominal features correspond to nominal locations of the set of pins of the chuck. In step 508, the test wafer is transferred from the chuck to the feature plate of the measurement device. In step 510, a set of measurement images are acquired of the markings on the pressure-sensitive features of the test wafer. In step 512, a misalignment vector between the test wafer and the chuck is determined by comparing the calibration images of the nominal features to the measurement images to the markings on the pressure-sensitive features.

One skilled in the art will recognize that the herein described components, operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken as limiting.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

1. A system comprising:
a robot;
a measurement device including a plate, wherein the plate includes a plurality of nominal measurement features, wherein the measurement device includes a plurality of cameras,
wherein the robot is configured to transfer a test wafer between a chuck of a process tool and the measurement device, wherein the test wafer includes a plurality of pressure-sensitive features distributed across the test wafer, wherein a respective pressure-sensitive features is markable by a respective pin of a plurality of pins of the chuck;
a controller including one or more processors and a memory medium, wherein the one or more processors are configured to execute program instructions stored on the memory medium, wherein the program instructions are configured to cause the one or more processors to:
direct the robot to place the test wafer onto the plurality of pins of the chuck of the process tool such that each pressure-sensitive feature is marked by a corresponding pin of the plurality of pins;
direct the plurality of cameras of the measurement device to acquire a plurality of calibration images of the plurality of nominal measurement features of the plate of the measurement device, wherein the plurality of nominal measurement features correspond to nominal locations of the plurality of pins of the chuck;
direct the robot to transfer the test wafer to the measurement device; direct the plurality of cameras to acquire a plurality of measurement images of a plurality of markings formed on the plurality of pressure-sensitive; and
determine a misalignment vector between the test wafer and the chuck by comparing the plurality of measurement images of the plurality of markings formed on the plurality of pressure-sensitive features to the plurality of calibration images of the plurality of nominal measurement features.

2. The system of claim 1, wherein the one or more processors are further configured to:
direct the robot to adjust a position of a subsequent wafer to compensate for the determined misalignment vector between the test wafer and the chuck.

3. The system of claim 1, wherein the plurality of pressure-sensitive features comprises:
a plurality of deformable features.

4. The system of claim 3, wherein each deformable feature is secured within a respective through-hole of the test wafer and spans a portion of the respective through-hole, wherein the respective deformable feature does not contact an edge of the respective through-hole.

5. The system of claim 3, wherein each deformable feature is affixed to a surface of the test wafer.

6. The system of claim 3, wherein one or more of the deformable features are formed from a deformable material.

7. The system of claim 6, wherein the deformable material comprises a metal.

8. The system of claim 7, wherein the metal comprises at least one of indium, tin, copper, or lead.

9. The system of claim 7, wherein the metal is 300 to 800 μm thick.

10. The system of claim 1, wherein the plurality of pressure-sensitive features comprises:
a plurality of color-changing features, wherein each color-changing feature is affixed on a surface of the test wafer.

11. The system of claim 1, wherein the test wafer is formed from at least one of carbon fiber, silicon, aluminum, or quartz.

12. The system of claim 1, wherein the one or more processors are further configured to cause a respective camera to acquire a respective calibration image of the plate of the measurement device.

13. The system of claim 1, wherein the one or more processors are further configured to cause a respective camera to acquire a respective measurement image of a respective marking of a respective pressure-sensitive feature.

14. The system of claim 1, the determine a misalignment vector between the test wafer and the chuck by comparing the plurality of measurement images of the plurality of markings formed on the plurality of pressure-sensitive features to the plurality of calibration images of the plurality of nominal measurement features comprises:
determine a center of a geometric shape defined by the plurality of markings formed on the plurality of pressure-sensitive features;
determine a center of the geometric shape defined by the plurality of nominal measurement features formed on the plate of the measurement device; and
compare a first center of the geometric shaped defined by the plurality of markings formed on the plurality of pressure-sensitive features to a second center of the geometric shape defined by the plurality of nominal measurement features formed on the plate of the measurement device.

15. The system of claim 14, wherein the geometric shape defined by the plurality of markings formed on the plurality of pressure-sensitive features and the geometric shape defined by the plurality of nominal measurement features formed on the plate of the measurement device comprises:
at least one of polygon or an ellipse.

16. The system of claim 15, the polygon comprises at least one of a triangle, a quadrilateral, a pentagon, a hexagon, or an octagon.

17. A method comprising:
providing a test wafer including a plurality of pressure-sensitive features distributed across the test wafer;
placing, with a robot, the test wafer onto a plurality of pins of a chuck of a process tool to form a plurality of markings on the plurality of pressure-sensitive features, wherein a respective marking is formed on a respective pressure-sensitive feature;
acquiring, with a plurality of cameras, a plurality of calibration images of a plurality of nominal measurement features formed on a plate of a measurement device, the plurality of nominal measurement features corresponding to nominal locations of the plurality of pins of the chuck;
transferring, with the robot, the test wafer from the chuck of the process tool to the plate of the measurement device;
acquiring, with the plurality of cameras, a plurality of measurement images of the plurality of markings formed on the plurality of pressure-sensitive features; and
determining a misalignment vector between the test wafer and the chuck by comparing the plurality of measurement images of the plurality of markings formed on the plurality of pressure-sensitive features to the plurality of calibration images of the plurality of nominal measurement features formed on the plate of the measurement device.

18. The method of claim 17, determining a misalignment vector between the test wafer and the chuck by comparing the plurality of measurement images of the plurality of markings formed on the plurality of pressure-sensitive features to the plurality of calibration images of the plurality of nominal measurement features formed on the plate of the measurement device comprises:
applying a pattern recognition algorithm to identify a plurality of locations corresponding to the plurality of nominal measurement features formed on the plate;
applying the pattern recognition algorithm to identify the plurality of locations of the plurality of markings formed on the plurality of pressure-sensitive features; and
comparing the plurality of locations corresponding to the plurality of locations of the plurality of markings formed on the plurality of pressure-sensitive features to the plurality of locations corresponding to the plurality of nominal measurement features formed on the plate.

19. The method of claim 17, wherein the plurality of pressure-sensitive features comprises:
at least one of a plurality of deformable features or a plurality of color-changing features.

20. A measurement wafer comprising:
a plurality of pressure-sensitive features distributed across a surface of a test wafer in a geometric pattern, wherein each pressure-sensitive feature includes a pressure-sensitive material responsive to application of pressure, wherein the pressure sensitive material comprises at least one of a deformable material or a color-changing material.
